(19) United States
(12) Patent Application Publication
(10) Pub. No.: US 2025/0330134 A1
(43) Pub. Date: Oct. 23, 2025

(54) RADIO FREQUENCY MODULE AND COMMUNICATION DEVICE

(71) Applicant: Murata Manufacturing Co., Ltd., Nagaokakyo-shi (JP)

(72) Inventor: Keisuke ARIMA, Nagaokakyo-shi (JP)

(73) Assignee: Murata Manufacturing Co., Ltd., Nagaokakyo-shi (JP)

(21) Appl. No.: 18/970,916

(22) Filed: Dec. 6, 2024

(30) Foreign Application Priority Data
Apr. 19, 2024 (JP) 2024-068489

(51) Int. Cl. H03F 3/24; H03F 1/26; H03F 1/30

(52) U.S. Cl. CPC H03F 3/245; H03F 1/26; H03F 1/30; H03F 2200/451; H03F 2200/468

(57) ABSTRACT

A radio frequency module includes a module substrate, a transmission filter disposed on the module substrate, an integrated circuit that is disposed on the module substrate and includes a temperature sensor, resin members that at least partly cover the transmission filter and the integrated circuit, and a metal shield that at least partly covers surfaces of the resin member. The transmission filter and the integrated circuit 81 are in contact with the metal shield.

### CROSS-REFERENCE TO RELATED APPLICATION

This application claims priority to Japanese Patent Application No. JP 2024-068489 filed on Apr. 19, 2024. The entire contents of the above-identified applications, including the specifications, drawings and claims, are incorporated herein by reference in their entirety.

### BACKGROUND OF THE DISCLOSURE

### 1. Field of the Disclosure

The present disclosure relates to a radio frequency module and a communication device.

### 2. Description of the Related Art

Japanese Unexamined Patent Application Publication No. 2022-07366 discloses, in a radio frequency module including a power amplifier (PA) control circuit stacked on a power amplifier, the inclusion of a temperature sensor for measuring the temperature of the power amplifier in the PA control circuit.

### SUMMARY OF THE DISCLOSURE

However, the temperature of a transmission filter cannot be measured in radio frequency modules in the related art. Accordingly, it may be difficult to suppress deterioration and/or a failure due to the heat of the transmission filter.

The present disclosure provides a radio frequency module and a communication device with which deterioration and/or a failure due to the heat of a transmission filter can be suppressed.

A radio frequency module according to an aspect of the present disclosure includes a module substrate, a transmission filter disposed on the module substrate, an integrated circuit that is disposed on the module substrate and includes a temperature sensor, a resin member that at least partly covers the transmission filter and the integrated circuit, and a metal shield that at least partly covers a surface of the resin member. The transmission filter and the integrated circuit are in contact with the metal shield.

A communication device according to an aspect of the present disclosure includes a signal processing circuit configured to process a radio frequency signal and the above-described radio frequency module. The radio frequency module is configured to transmit the radio frequency signal between the signal processing circuit and an antenna.

According to the present disclosure, deterioration and/or a failure due to the heat of a transmission filter can be suppressed.

### BRIEF DESCRIPTION OF THE DRAWINGS

FIG. 1 is a diagram illustrating the circuit configuration of a communication device according to a first embodiment;

FIG. 2 is a plan view of the radio frequency module according to the first embodiment;

FIG. 3 is a plan view of the radio frequency module according to the first embodiment;

FIG. 4 is a cross-sectional view of the radio frequency module according to the first embodiment;

FIG. 5 is a plan view of a radio frequency module according to a second embodiment;

FIG. 6 is a cross-sectional view of the radio frequency module according to the second embodiment;

FIG. 7 is a plan view of a radio frequency module according to a third embodiment;

FIG. 8 is a plan view of the radio frequency module according to the third embodiment;

FIG. 9 is a cross-sectional view of the radio frequency module according to the third embodiment;

FIG. 10 is a plan view of a radio frequency module according to a fourth embodiment;

FIG. 11 is a plan view of the radio frequency module according to the fourth embodiment; and

FIG. 12 is a cross-sectional view of the radio frequency module according to the fourth embodiment.

### DESCRIPTION OF THE PREFERRED EMBODIMENTS

Embodiments of the present disclosure will be described in detail below with reference to drawings. The embodiments to be described below each illustrate a comprehensive or concrete example. The numerical values, shapes, materials, constituent elements, arrangements of the constituent elements, the ways in which the constituent elements are connected, and so forth described in the following embodiments are merely examples and are not intended to limit the present disclosure.

The drawings are schematically illustrated with appropriate accentuation, omission, or proportion adjustment to depict the present disclosure and are not necessarily illustrated in an exact manner, and the shape, positional relationship, and proportion may be different from actual ones. In the drawings, configurations that are substantially the same as each other may be denoted by the same symbol and repeated description thereof may be omitted or simplified.

In the drawings to be referred to below, the X axis and the Y axis are axes perpendicular to each other on a plane parallel to main surfaces of a module substrate. The Z axis is perpendicular to the main surfaces of the module substrate, a positive Z axis direction indicates an upward direction, and a negative Z axis direction indicates a downward direction.

In the following description, the expression “connected” includes not only the case in which a circuit element is directly connected to another circuit element by a connection terminal and/or a wiring conductor but also the case in which a circuit element is electrically connected to another circuit element via still another circuit element. The expression “directly connected” means that a circuit element is directly connected to another circuit element by a connection terminal and/or a wiring conductor without still another circuit element. The expression “C is connected between A and B” means that one end of C is connected to A and the other end of C is connected to B and means that C is disposed in series on a path connecting A and B to each other. The “path connecting A and B to each other” means a path formed by a conductor that electrically connects A to B.

A “terminal” means a point where a conductor inside an element ends. In the case where the impedance of a conductor between elements is sufficiently low, a terminal is interpreted as being any point on the conductor between the elements or the entire conductor, rather than just a single point.

A “passband of a filter” is a portion of a frequency spectrum to be transmitted by a filter, and is defined as a frequency band in which output power is not attenuated by 3 dB or more below the maximum output power. Accordingly, the passband of a bandpass filter is defined as a frequency range between two points where the output power is attenuated by 3 dB below the maximum output power.

A “transmission band” means a frequency band used for transmission in a communication device, and a “reception band” means a frequency band used for reception in the communication device. For example, in a frequency division duplex (FDD) band, mutually different frequency bands (e.g., an uplink band and a downlink band) are used as a transmission band and a reception band. For example, in a time division duplex (TDD) band, the same frequency band is used as the transmission band and the reception band.

A “plan view of a module substrate” means orthographically projecting and viewing an object onto the XY plane in a negative direction of the Z axis. The expression “A and B overlap in plan view” means that the region of A orthographically projected onto the XY plane overlaps the region of B orthographically projected onto the XY plane.

The expression “a component is disposed on a module substrate” includes the case where the component is disposed on the main surface of the module substrate and the case where the component is disposed in the module substrate. The expression “the component is disposed on the main surface of the module substrate” includes not only the case where the component is disposed on the main surface in a state of being in contact with the main surface of the module substrate but also the case where the component is disposed above the main surface without being in contact with the main surface of the module substrate (e.g., the case where the component is stacked on another component disposed in contact with the main surface). The expression “the component is disposed on the main surface of the module substrate” may include the case where the component is disposed in a recess portion formed on the main surface of the module substrate.

The expression “A is disposed between B and C” means that at least one of a plurality of line segments connecting any point inside B and any point inside C passes through A. The expression “A is closer to C than B” means that the distance between A and C is shorter than the distance between B and C. The “distance between A (B) and C” means the length of the shortest one of a plurality of line segments connecting any point inside A (B) and any point inside C.

Terms indicating a relationship between elements, such as “parallel” and “perpendicular”, terms indicating the shape of an element, such as “straight line”, and numerical ranges do not only represent strict meanings, but also include substantially equivalent ranges, such as errors of several percent.

### First Embodiment

A first embodiment will be described. A communication device 5 according to the present embodiment can be used to provide a wireless connection. For example, the communication device 5 can be installed in user equipment (UE) in a cellular network (also referred to as a mobile network), such as a cellular phone, a smartphone, a tablet computer, or a wearable device. In another example, the installation of the communication device 5 can establish wireless connections in an Internet of Things (IoT) sensor device, a medical/healthcare device, a vehicle, an unmanned aerial vehicle (UAV) (so-called drone), and an automated guided vehicle (AGV). In still another example, the installation of the communication device 5 can establish wireless connections at wireless access points or wireless hotspots.

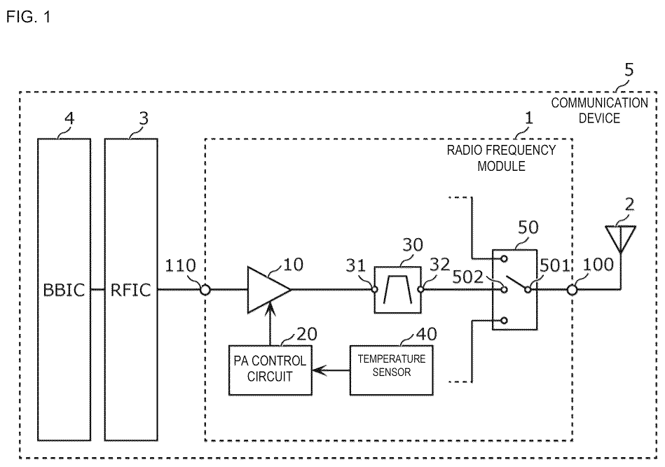

The circuit configuration of the communication device 5 according to the present embodiment and a radio frequency module 1 according to the present embodiment will be described with reference to FIG. 1. FIG. 1 is a diagram illustrating the circuit configuration of the communication device 5 according to the present embodiment.

The circuit configuration illustrated in FIG. 1 is an example, and the communication device 5 can be installed using any of various circuit installations and circuit techniques. Accordingly, the following description of the communication device 5 should not be interpreted in a limited manner.

### 1.1 Circuit Configuration of the Communication Device 5

First, the circuit configuration of the communication device 5 according to the present embodiment will be described with reference to FIG. 1. The communication device 5 includes the radio frequency module 1, an antenna 2, and a radio frequency integrated circuit (RFIC) 3, and a baseband integrated circuit (BBIC) 4.

The radio frequency module 1 can transmit a radio frequency signal between the antenna 2 and the RFIC 3. The circuit configuration of the radio frequency module 1 will be described below.

The antenna 2 is connected to an antenna connection terminal 100 of the radio frequency module 1. The antenna 2 can receive a radio frequency signal from the radio frequency module 1 and output the radio frequency signal to the outside of the communication device 5. The antenna 2 may receive a radio frequency signal from the outside of the communication device 5 and output the radio frequency signal to the radio frequency module 1. The antenna 2 does not necessarily have to be included in the communication device 5. The communication device 5 may include one or more antennas in addition to the antenna 2.

The RFIC 3 is an example of a signal processing circuit for processing a radio frequency signal.

Specifically, the RFIC 3 can perform signal processing, such as up-conversion, upon a transmission signal input from the BBIC 4 and output a radio frequency transmission signal generated as a result of the signal processing to the radio frequency module 1. The RFIC 3 may perform signal processing, such as down-conversion, upon a radio frequency reception signal input via a reception path (not illustrated) in the radio frequency module 1 and output a reception signal generated as a result of the signal processing to the BBIC 4. The RFIC 3 may include a control unit for controlling, for example, a switch and a power amplifier included in the radio frequency module 1. The function of the control unit in the RFIC 3 may be partially or entirely implemented outside the RFIC 3 and may be implemented in, for example, the BBIC 4 or the radio frequency module 1.

The BBIC 4 is a baseband signal processing circuit for performing signal processing using a frequency band lower than the frequency of a radio frequency signal transmitted by the radio frequency module 1. Examples of a signal processed by the BBIC 4 include an image signal for image display and/or an audio signal for conversation through a speaker. The BBIC 4 does not necessarily have to be included in the communication device 5.

### 1.2 Circuit Configuration of the Radio Frequency Module 1

Next, the circuit configuration of the radio frequency module 1 according to the present embodiment will be described with reference to FIG. 1 The radio frequency module 1 includes a power amplifier 10, a PA control circuit 20, a transmission filter 30, a temperature sensor 40, a switch circuit 50, the antenna connection terminal 100, and a radio frequency input terminal 110.

The antenna connection terminal 100 is an external connection terminal of the radio frequency module 1, is connected to the antenna 2 outside the radio frequency module 1, and is connected to the switch circuit 50 in the radio frequency module 1.

The radio frequency input terminal 110 is an external connection terminal of the radio frequency module 1, is connected to the RFIC 3 outside the radio frequency module 1, and is connected to the power amplifier 10 in the radio frequency module 1.

The power amplifier 10 can amplify a transmission signal in a band A received via the radio frequency input terminal 110 with power supplied from a power supply (not illustrated). The input end of the power amplifier 10 is connected to the radio frequency input terminal 110, and the output end of the power amplifier 10 is connected to the transmission filter 30.

The power amplifier 10 does not necessarily have to be partially or entirely included in the radio frequency module 1. In this case, the power amplifier 10 may be partially or entirely connected between the RFIC 3 and the radio frequency input terminal 110 or may be included in the RFIC 3.

The PA control circuit 20 can control the power amplifier 10. Specifically, the PA control circuit 20 outputs a control signal for controlling the power amplifier 10 to the power amplifier 10 on the basis of, for example, a control signal from the RFIC 3 and/or a sensor signal from the temperature sensor 40. As a result, for example, a bias current supplied to the power amplifier 10 is controlled.

The transmission filter 30 is a bandpass filter having a pass band including a transmission band in a predetermined band. The transmission filter 30 includes a terminal 31 connected to the power amplifier 10 and a terminal 32 connected to the switch circuit 50. The transmission filter 30 is not limited to a bandpass filter.

The communication band is a frequency band for a communication system that is built using the radio access technology (RAT). The communication band is defined in advance by standards bodies or the likes (e.g., the 3rd generation partnership project (3GPP (registered trademark)) and the institute of electrical and electronics engineers (IEEE)). Examples of the communication system include the 5th Generation New Radio (5G NR) system, the long term evolution (LTE) system, and the wireless local area network (WLAN) system.

The temperature sensor 40 can detect a temperature and output a sensor signal to the PA control circuit 20. The temperature sensor 40 may output a sensor signal to the RFIC 3 instead of or in addition to the PA control circuit 20. The temperature sensor 40 is formed by, for example, a semiconductor diode.

The switch circuit 50 is connected between the antenna connection terminal 100 and each of a plurality of filters including the transmission filter 30 (the illustration of the filters other than the transmission filter 30 is omitted). The switch circuit 50 includes a common terminal 501 and a plurality of selection terminals (including a selection terminal 502). The common terminal 501 is connected to the antenna connection terminal 100. The selection terminal 502 is connected to the transmission filter 30. Each of the other selection terminals is connected to a transmission filter (not illustrated) and/or a reception filter (not illustrated).

In this connection configuration, the switch circuit 50 can connect the common terminal 501 to the multiple selection terminals in response to, for example, a control signal from the RFIC 3. The switch circuit 50 is, for example, a multi-connection-type switch circuit.

The circuit configuration of the radio frequency module 1 is an example and is not limited to the circuit configuration illustrated in FIG. 1. For example, the radio frequency module 1 may further include a switch circuit that is connected between each of a plurality of filters and the power amplifier 10 and can switch between connections between the power amplifier 10 and the multiple filters.

### 1.3 Installation Example of the Radio Frequency Module 1

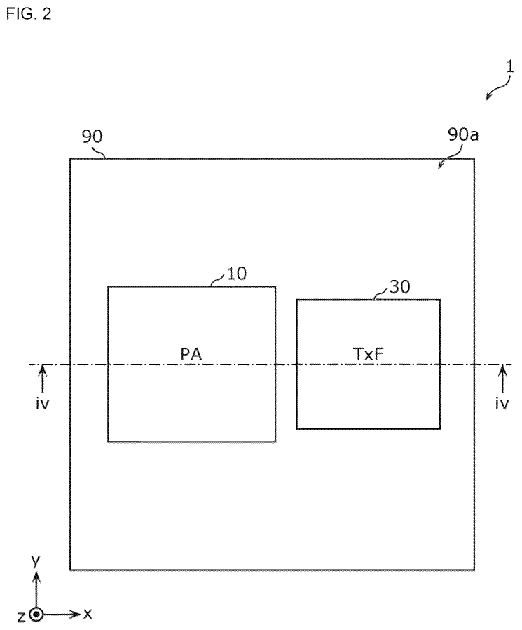

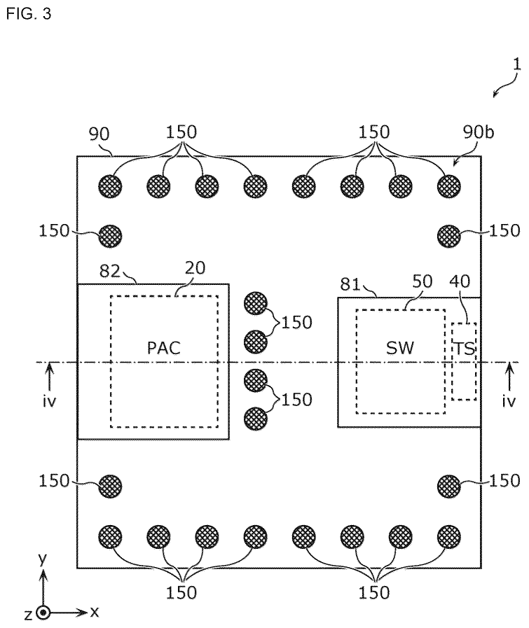

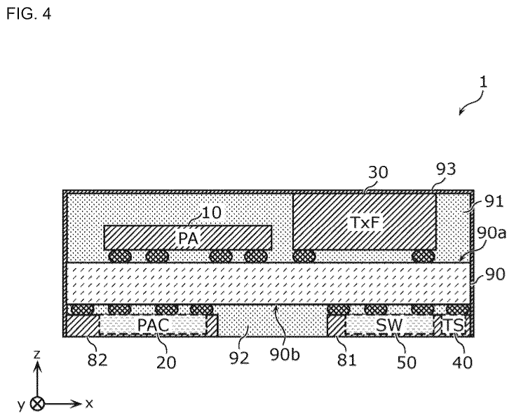

Next, the installation example of the radio frequency module 1 having the above circuit configuration will be described with reference to FIGS. 2 to 4. FIG. 2 is a plan view of the radio frequency module 1 according to the present embodiment, with a main surface 90a of a module substrate 90 viewed from a Z-axis positive side. FIG. 3 is a plan view of the radio frequency module 1 according to the present embodiment, with a main surface 90b of the module substrate 90 seen through from the Z-axis positive side. FIG. 4 is a cross-sectional view of the radio frequency module 1 according to the present embodiment. The cross section of the radio frequency module 1 in FIG. 4 is taken along line iv-iv in FIGS. 2 and 3.

In FIGS. 2 to 4, some of components are provided with letters representing the components so that the arrangement relationship of the components can be easily understood, but actual components do not necessarily have to be provided with such letters. In FIGS. 2 and 3, the illustration of resin members 91 and 92 covering components on the main surfaces 90a and 90b of the module substrate 90 and a metal shield 93 covering the surfaces of the resin members 91 and 92 is omitted.

FIGS. 2 to 4 illustrate an exemplary configuration of the radio frequency module 1, and the radio frequency module 1 can be installed using any of various circuit installations and circuit techniques. Accordingly, the following description of the radio frequency module 1 should not be interpreted in a limited manner.

The radio frequency module 1 includes integrated circuits 81 and 82, the module substrate 90, the resin members 91 and 92, the metal shield 93, and a plurality of external connection terminals 150 in addition to the multiple circuit components illustrated in FIG. 1.

The module substrate 90 has the main surfaces 90a and 90b facing each other. The main surface 90a is an example of a first main surface and may sometimes be called a top surface or a front surface. The main surface 90b is an example of a second main surface and may sometimes be called a bottom surface or a back surface. For example, wiring lines (not illustrated) and via conductors (not illustrated) are formed in the module substrate 90 and on the main surfaces 90a and 90b. The shape of the module substrate 90 are rectangular in plan view in the present embodiment, but is not limited to a rectangle.

Although a low temperature co-fired ceramic (LTCC) substrate or a high temperature co-fired ceramic (HTCC) substrate having a laminated structure of a plurality of dielectric layers, a component built-in substrate, a substrate including a redistribution layer (RDL), or a printed circuit board can be used as the module substrate 90, a substrate serving as the module substrate 90 is not limited thereto.

The resin members 91 and 92 at least partly cover the main surfaces 90a and 90b of the module substrate 90 and components on the main surfaces 90a and 90b, respectively. The material of the resin members 91 and 92 is, but is not limited to, for example, an epoxy resin. The resin members 91 and 92 have functions of ensuring reliability, such as mechanical strength and moisture resistance, of the components on the main surfaces 90a and 90b, respectively.

The metal shield 93 is a metal thin film formed by, for example, sputtering. The metal shield 93 is formed to partly cover the surface (top surface and side surfaces) of the resin members 91 and 92. The metal shield 93 is connected to the ground, suppresses entrance of external noise into the electronic components forming the radio frequency module 1, and suppresses interference with another module or another device due to noise generated in the radio frequency module 1.

The components disposed on the main surface 90a of the module substrate 90 will be described with reference to FIGS. 2 to 4.

The power amplifier 10 (PA) is disposed on the main surface 90a of the module substrate 90. The power amplifier 10 is not in contact with the metal shield 93. That is, the power amplifier 10 is not directly and physically connected to the metal shield 93.

The power amplifier 10 is installed as a semiconductor integrated circuit. As a semiconductor material, for example, silicon germanium (SiGe) or gallium arsenide (GaAs) can be used. At that time, the power amplifier 10 can be partially or entirely formed by a hetero junction bipolar transistor (HBT). As a semiconductor material, gallium nitride (GaN) or silicon carbide (SiC) can also be used. At that time, the power amplifier 10 can be partially or entirely formed by a high-electron-mobility transistor (HEMT) or a metal semiconductor field-effect transistor (MESFET). As a semiconductor material, silicon (Si) can also be used. At that time, the power amplifier 10 may be partially or entirely formed by a complementary metal oxide semiconductor (CMOS) and may be produced by a silicon on insulator (SOI) process.

The transmission filter 30 (TxF) is disposed on the main surface 90a of the module substrate 90 and is in contact with the metal shield 93. That is, the transmission filter 30 is directly and physically connected to the metal shield 93. More specifically, the top surface of the transmission filter 30 is at least partly exposed from the resin member 91 and is in contact with the metal shield 93. The top surface of the transmission filter 30 is one of two main surfaces of the transmission filter 30 facing each other which is opposite to the other one of them facing the main surface 90a of the module substrate 90.

The transmission filter 30 may be, but is not limited to, a surface acoustic wave (SAW) filter, a bulk acoustic wave (BAW) filter, an LC resonant filter, a dielectric resonant filter, or any combination of these filters.

Next, the components disposed on the main surface 90b of the module substrate 90 will be described with reference to FIGS. 3 to 4.

The integrated circuit 81 is a semiconductor integrated circuit including the switch circuit 50 (SW) and the temperature sensor 40 (TS) and is disposed on the main surface 90b of the module substrate 90. The integrated circuit 81 is in contact with the metal shield 93. That is, the integrated circuit 81 is directly and physically connected to the metal shield 93. Specifically, the side surface of the integrated circuit 81 is at least partly in contact with a part of the metal shield 93 formed on the side surface of the radio frequency module 1. In the integrated circuit 81, the temperature sensor 40 is closer to the metal shield 93 than the switch circuit 50. Specifically, the temperature sensor 40 is closer to the contact portion of the integrated circuit 81 with the metal shield 93 than the switch circuit 50.

The integrated circuit 81 does not necessarily have to include the switch circuit 50 and may be, for example, an integrated circuit dedicated for the temperature sensor 40. In this case, the switch circuit 50 may be included in another integrated circuit (e.g., the integrated circuit 82 or a new integrated circuit) different from the integrated circuit 81. The integrated circuit 81 may include a switch circuit (not illustrated) connected between the power amplifier 10 and each of the multiple filters instead of or in addition to the switch circuit 50.

The integrated circuit 82 is a semiconductor integrated circuit including the PA control circuit 20 (PAC) and is disposed on the main surface 90b of the module substrate 90. The integrated circuit 82 is in contact with the metal shield 93. The integrated circuit 82 does not necessarily have to be in contact with the metal shield 93.

Each of the integrated circuits 81 and 82 may be formed by, for example, a complementary metal oxide semiconductor (CMOS) and, in this case, may be produced by an SOI process. Each of the integrated circuits 81 and 82 is not limited to a CMOS.

The integrated circuit 82 may be integrated into the integrated circuit 81. That is, the integrated circuit 81 may include the PA control circuit 20 in addition to the switch circuit 50 and the temperature sensor 40.

### 1.4. Summarization

As described above, the radio frequency module 1 according to the present embodiment includes the module substrate 90, the transmission filter 30 disposed on the module substrate 90, the integrated circuit 81 that is disposed on the module substrate 90 and includes the temperature sensor 40, the resin members 91 and 92 that at least partly cover the transmission filter 30 and the integrated circuit 81, and the metal shield 93 that at least partly covers surfaces of the resin members 91 and 92. The transmission filter 30 and the integrated circuit 81 are in contact with the metal shield 93.

With this configuration in which both the transmission filter 30 and the integrated circuit 81 are in contact with the metal shield 93, the integrated circuit 81 is thermally connected to the transmission filter 30 via the metal shield 93. Since the thermal conductivity of the metal shield 93 is higher than that of the resin members 91 and 92, the measurement accuracy and/or time response of the temperature of the transmission filter 30 can be improved. Assuming the power amplifier 10 is controlled on the basis of the temperature of the transmission filter 30 measured as described above, deterioration and/or a failure due to the heat of the transmission filter 30 can be suppressed.

For example, the radio frequency module 1 according to the present embodiment may further include the power amplifier 10 that is disposed on the module substrate 90 and is connected to the transmission filter 30. The power amplifier 10 does not necessarily have to be in contact with the metal shield 93.

With this configuration in which the power amplifier 10 is not in contact with the metal shield 93, the transfer of heat from the power amplifier 10 to the temperature sensor 40 via the metal shield 93 can be suppressed and the accuracy of measuring the temperature of the transmission filter 30 can be further improved.

For example, in the radio frequency module 1 according to the present embodiment, the module substrate 90 may have the main surfaces 90a and 90b facing each other. The transmission filter 30 and the power amplifier 10 may be disposed on the main surface 90a, and the integrated circuit 81 may be disposed on the main surface 90b.

With this configuration, the power amplifier 10, the transmission filter 30, and the integrated circuit 81 can be dispersedly disposed on the two main surfaces 90a and 90b of the module substrate 90. This can contribute to the miniaturization of the radio frequency module 1.

For example, the radio frequency module 1 according to the present embodiment may further include the switch circuit 50 that is connected between the transmission filter 30 and the antenna connection terminal 100 and is included in the integrated circuit 81.

With this configuration in which the temperature sensor 40 and the switch circuit 50 are included in the single integrated circuit 81, the number of components can be reduced as compared with the case where the temperature sensor 40 and the switch circuit 50 are installed in the two respective components.

For example, in the radio frequency module 1 according to the present embodiment, the temperature sensor 40 may be closer to the metal shield 93 than the switch circuit 50 in the integrated circuit 81.

With this configuration, the temperature sensor 40 can be disposed more closer to the metal shield 93. Accordingly, the heat transfer path from the transmission filter 30 to the temperature sensor 40 via the metal shield 93 can be shortened and the measurement accuracy and/or time response of the temperature of the transmission filter 30 can be further improved.

The communication device 5 according to the present embodiment includes the RFIC 3 configured to process a radio frequency signal and the radio frequency module 1 configured to transmit the radio frequency signal between the RFIC 3 and the antenna 2.

With this configuration, the effect of the above radio frequency module 1 can be obtained in the communication device 5.

### Second Embodiment

Next, the second embodiment will be described. The present embodiment mainly differs from the above first embodiment in that the temperature sensor is not included in the integrated circuit including the switch circuit but in the integrated circuit including the PA control circuit. The present embodiment will be described below with reference to the drawings, focusing on points different from the first embodiment.

The circuit configuration of a radio frequency module according to the present embodiment is the same as that of the radio frequency module 1 according to the first embodiment, and the illustration and description thereof will therefore be omitted.

### 2.1 Installation Example of Radio Frequency Module 1A

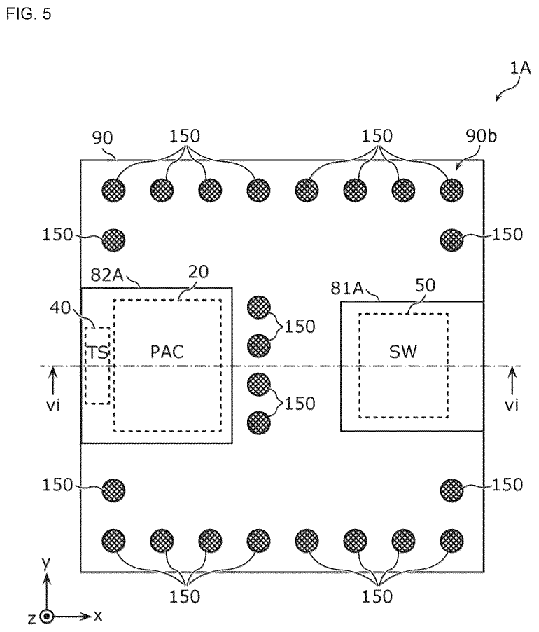

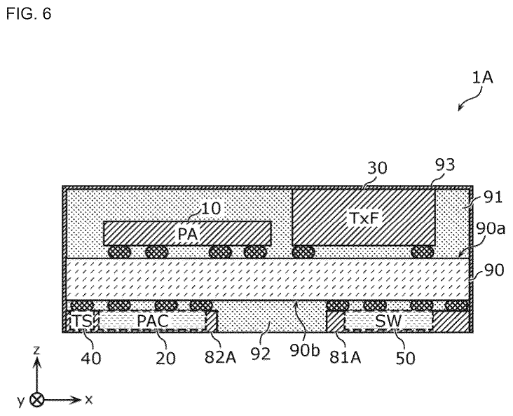

The installation example of a radio frequency module 1A will be described with reference to FIGS. 5 and 6. FIG. 5 is a plan view of the radio frequency module 1A according to the present embodiment, with the main surface 90b of the module substrate 90 seen through from the Z-axis positive side. FIG. 6 is a cross-sectional view of the radio frequency module 1A according to the present embodiment. The cross section of the radio frequency module 1A in FIG. 6 is taken along line vi-vi in FIG. 5. The plan view of the radio frequency module 1A according to the present embodiment in which the main surface 90a of the module substrate 90 is viewed is the same FIG. 2 in the first embodiment, and the illustration thereof will be omitted.

In FIGS. 5 and 6, some of components are provided with letters representing the components so that the arrangement relationship of the components can be easily understood, but actual components do not necessarily have to be provided with such letters. In FIG. 5, the illustration of the resin member 92 covering components on the main surface 90b of the module substrate 90 and the metal shield 93 covering the surface of the resin member 92 is omitted.

FIGS. 5 and 6 illustrate an exemplary configuration of the radio frequency module 1A, and the radio frequency module 1A can be installed using any of various circuit installations and circuit techniques. Accordingly, the following description of the radio frequency module 1A should not be interpreted in a limited manner.

The radio frequency module 1A includes integrated circuits 81A and 82A, the module substrate 90, the resin members 91 and 92, the metal shield 93, and the multiple external connection terminals 150 in addition to the multiple circuit components illustrated in FIG. 1.

The integrated circuit 81A is a semiconductor integrated circuit including the switch circuit 50 (SW) and is disposed on the main surface 90b of the module substrate 90. The integrated circuit 81A is in contact with the metal shield 93. The integrated circuit 81A does not necessarily have to be in contact with the metal shield 93.

The integrated circuit 82A is a semiconductor integrated circuit including the PA control circuit 20 (PAC) and the temperature sensor 40 (TS) and is disposed on the main surface 90b of the module substrate 90. The integrated circuit 82A is in contact with the metal shield 93. That is, the integrated circuit 82A is directly and physically connected to the metal shield 93. Specifically, the side surface of the integrated circuit 82A is at least partly in contact with a part of the metal shield 93 formed on the side surface of the radio frequency module 1A. In the integrated circuit 82A, the temperature sensor 40 is closer to the metal shield 93 than the PA control circuit 20. Specifically, the temperature sensor 40 is closer to the contact portion of the integrated circuit 82A with the metal shield 93 than the PA control circuit 20.

The integrated circuit 82A does not necessarily have to include the PA control circuit 20 and may be, for example, an integrated circuit dedicated for the temperature sensor 40. In this case, the PA control circuit 20 may be included in another integrated circuit (e.g., the integrated circuit 81A or a new integrated circuit) different from the integrated circuit 82A.

Each of the integrated circuits 81A and 82A may be formed by, for example, a CMOS, and in this case, may be produced by an SOI process. Each of the integrated circuits 81A and 82A is not limited to a CMOS.

The integrated circuit 81A may be integrated into the integrated circuit 82A. That is, the integrated circuit 82A may include the switch circuit 50 in addition to the PA control circuit 20 and the temperature sensor 40.

### 2.2. Summarization

As described above, the radio frequency module 1A according to the present embodiment includes the module substrate 90, the transmission filter 30 disposed on the module substrate 90, the integrated circuit 82A that is disposed on the module substrate 90 and includes the temperature sensor 40, the resin members 91 and 92 that at least partly cover the transmission filter 30 and the integrated circuit 82A, and the metal shield 93 that at least partly covers surfaces of the resin members 91 and 92. The transmission filter 30 and the integrated circuit 82A are in contact with the metal shield 93.

With this configuration in which both the transmission filter 30 and the integrated circuit 82A are in contact with the metal shield 93, the integrated circuit 82A is thermally connected to the transmission filter 30 via the metal shield 93. Since the thermal conductivity of the metal shield 93 is higher than that of the resin members 91 and 92, the measurement accuracy and/or time response of the temperature of the transmission filter 30 can be improved. Assuming the power amplifier 10 is controlled on the basis of the temperature of the transmission filter 30 measured as described above, deterioration and/or a failure due to the heat of the transmission filter 30 can be suppressed.

For example, the radio frequency module 1A according to the present embodiment may further include the power amplifier 10 that is disposed on the module substrate 90 and is connected to the transmission filter 30. The power amplifier 10 does not necessarily have to be in contact with the metal shield 93.

With this configuration in which the power amplifier 10 is not in contact with the metal shield 93, the transfer of heat from the power amplifier 10 to the temperature sensor 40 via the metal shield 93 can be suppressed and the accuracy of measuring the temperature of the transmission filter 30 can be further improved. For example, in the radio frequency module 1A

according to the present embodiment, the module substrate 90 may have the main surfaces 90a and 90b facing each other. The transmission filter 30 and the power amplifier 10 may be disposed on the main surface 90a, and the integrated circuit 82A may be disposed on the main surface 90b.

With this configuration, the power amplifier 10, the transmission filter 30, and the integrated circuit 82A can be dispersedly disposed on the two main surfaces 90a and 90b of the module substrate 90. This can contribute to the miniaturization of the radio frequency module 1A.

For example, the radio frequency module 1A according to the present embodiment may further include the PA control circuit 20 that is configured to control the power amplifier 10 and is included in the integrated circuit 82A.

With this configuration in which the temperature sensor 40 and the PA control circuit 20 are included in the single integrated circuit 82A, the number of components can be reduced as compared with the case where the temperature sensor 40 and the PA control circuit 20 are installed in the two respective components.

For example, in the radio frequency module 1A according to the present embodiment, the temperature sensor 40 may be closer to the metal shield 93 than the PA control circuit 20 in the integrated circuit 82A.

With this configuration, the temperature sensor 40 can be disposed more closer to the metal shield 93. Accordingly, the heat transfer path from the transmission filter 30 to the temperature sensor 40 via the metal shield 93 can be shortened and the measurement accuracy and/or time response of the temperature of the transmission filter 30 can be further improved.

The communication device 5 according to the present embodiment includes the RFIC 3 configured to process a radio frequency signal and the radio frequency module 1A configured to transmit the radio frequency signal between the RFIC 3 and the antenna 2.

With this configuration, the effect of the above radio frequency module 1A can be obtained in the communication device 5.

### Third Embodiment

Next, the third embodiment will be described. The present embodiment mainly differs from the above second embodiment in that the integrated circuit including the PA control circuit and the temperature sensor is stacked on the power amplifier 10. The present embodiment will be described below with reference to the drawings, focusing on points different from the second embodiment.

The circuit configuration of a radio frequency module according to the present embodiment is the same as that of the radio frequency module according to the first embodiment, and the illustration and description thereof will therefore be omitted.

### 3.1 Installation Example of Radio Frequency Module 1B

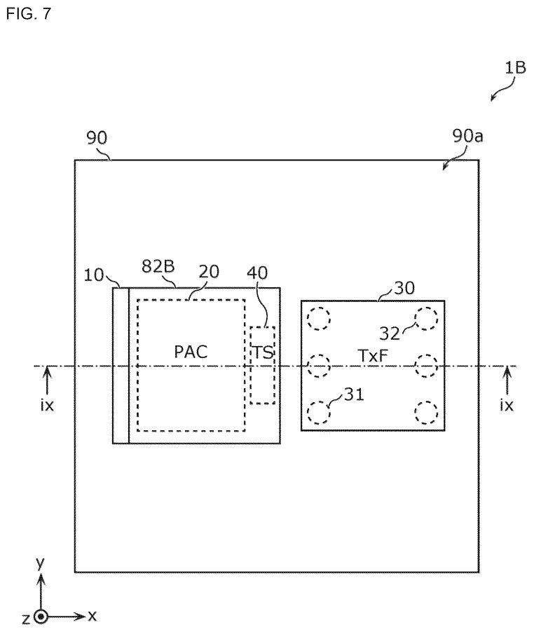

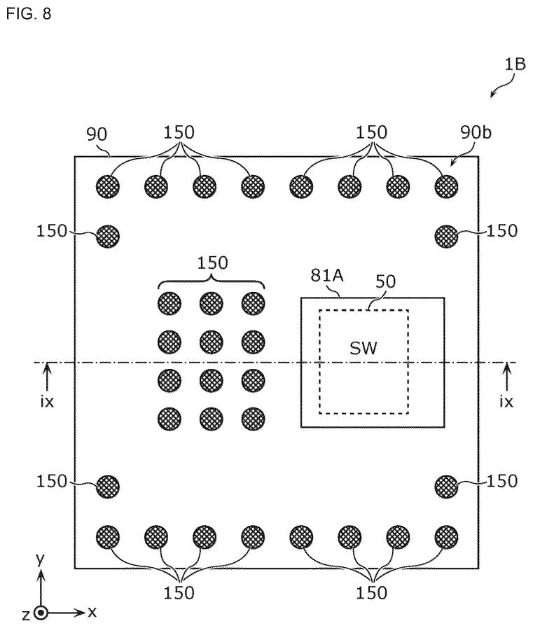

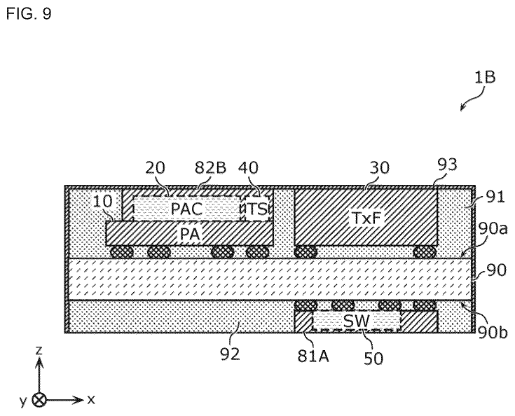

The installation example of a radio frequency module 1B will be described with reference to FIGS. 7 to 9. FIG. 7 is a plan view of the radio frequency module 1B according to the present embodiment, with the main surface 90a of the module substrate 90 viewed from the Z-axis positive side. FIG. 8 is a plan view of the radio frequency module 1B according to the present embodiment, with the main surface 90b of the module substrate 90 seen through from the Z-axis positive side. FIG. 9 is a cross-sectional view of the radio frequency module 1B according to the present embodiment. The cross section of the radio frequency module 1B in FIG. 9 is taken along line ix-ix in FIGS. 7 and 8.

In FIGS. 7 to 9, some of components are provided with letters representing the components so that the arrangement relationship of the components can be easily understood, but actual components do not necessarily have to be provided with such letters. In FIGS. 7 and 8, the illustration of the resin members 91 and 92 covering components on the main surfaces 90a and 90b of the module substrate 90 and the metal shield 93 covering the surfaces of the resin members 91 and 92 is omitted.

FIGS. 7 to 9 illustrate an exemplary configuration of the radio frequency module 1B, and the radio frequency module 1B can be installed using any of various circuit installations and circuit techniques. Accordingly, the following description of the radio frequency module 1B should not be interpreted in a limited manner.

The radio frequency module 1B includes the integrated circuit 81A, an integrated circuit 82B, the module substrate 90, the resin members 91 and 92, the metal shield 93, and the multiple external connection terminals 150 in addition to the multiple circuit components illustrated in FIG. 1.

Like in the first embodiment and the second embodiment, the transmission filter 30 (TxF) is disposed on the main surface 90a of the module substrate 90 and is in contact with the metal shield 93. The transmission filter 30 includes a plurality of external connection terminals including the terminals 31 and 32. The terminal 31 is an example of a first terminal, and the terminal 32 is an example of a second terminal. As illustrated in FIG. 7, the terminal 31 is closer to the integrated circuit 82B than the terminal 32.

The integrated circuit 82B is a semiconductor integrated circuit including the PA control circuit 20 (PAC) and the temperature sensor 40 (TS) and is disposed on the main surface 90a of the module substrate 90. Specifically, the integrated circuit 82B is stacked on the power amplifier 10. The integrated circuit 82B is in contact with the metal shield 93. That is, the integrated circuit 82B is directly and physically connected to the metal shield 93.

Specifically, the top surface of the integrated circuit 82B is at least partly in contact with a part of the metal shield 93 formed on the top surface of the radio frequency module 1B. In the integrated circuit 82B, the temperature sensor 40 is closer to the transmission filter 30 than the PA control circuit 20.

### 3.2. Summarization

As described above, the radio frequency module 1B according to the present embodiment includes the module substrate 90, the transmission filter 30 disposed on the module substrate 90, the integrated circuit 82B that is disposed on the module substrate 90 and includes the temperature sensor 40, the resin members 91 and 92 that at least partly cover the transmission filter 30 and the integrated circuit 82B, and the metal shield 93 that at least partly covers surfaces of the resin members 91 and 92. The transmission filter 30 and the integrated circuit 82B are in contact with the metal shield 93.

With this configuration in which both the transmission filter 30 and the integrated circuit 82B are in contact with the metal shield 93, the integrated circuit 82B is thermally connected to the transmission filter 30 via the metal shield 93. Since the thermal conductivity of the metal shield 93 is higher than that of the resin members 91 and 92, the measurement accuracy and/or time response of the temperature of the transmission filter 30 can be improved. Assuming the power amplifier 10 is controlled on the basis of the temperature of the transmission filter 30 measured as described above, deterioration and/or a failure due to the heat of the transmission filter 30 can be suppressed.

For example, the radio frequency module 1B according to the present embodiment may further include the power amplifier 10 that is disposed on the module substrate 90 and is connected to the transmission filter 30. The power amplifier 10 does not necessarily have to be in contact with the metal shield 93.

With this configuration in which the power amplifier 10 is not in contact with the metal shield 93, the transfer of heat from the power amplifier 10 to the temperature sensor 40 via the metal shield 93 can be suppressed and the accuracy of measuring the temperature of the transmission filter 30 can be further improved.

For example, in the radio frequency module 1B according to the present embodiment, the module substrate 90 may have the main surfaces 90a and 90b facing each other. The transmission filter 30, the integrated circuit 82B, and the power amplifier 10 may be disposed on the main surface 90a.

With this configuration in which the transmission filter 30, the integrated circuit 82B, and the power amplifier 10 are disposed on the single main surface 90a of the module substrate 90, a production process can be simplified.

For example, the radio frequency module 1B according to the present embodiment may further include the PA control circuit 20 that is configured to control the power amplifier 10 and is included in the integrated circuit 82B.

With this configuration in which the temperature sensor 40 and the PA control circuit 20 are included in the single integrated circuit 82B, the number of components can be reduced as compared with the case where the temperature sensor 40 and the PA control circuit 20 are installed in the two respective components.

For example, in the radio frequency module 1B according to the present embodiment, the temperature sensor 40 may be closer to the transmission filter 30 than the PA control circuit 20 in the integrated circuit 82B.

With this configuration, the temperature sensor 40 can be disposed more closer to the metal shield 93. Accordingly, the heat transfer path from the transmission filter 30 to the temperature sensor 40 via the metal shield 93 can be shortened and the measurement accuracy and/or time response of the temperature of the transmission filter 30 can be further improved.

For example, in the radio frequency module 1B according to the present embodiment, the transmission filter 30 may include the terminal 31 connected to the power amplifier 10 and the terminal 32 connected to the antenna connection terminal 100. The terminal 31 may be closer to the integrated circuit 82B than the terminal 32.

With this configuration, the terminal 31 can be disposed more closer to the integrated circuit 82B. A larger amount of current flows through the terminal 31 connected to the power amplifier 10 than the terminal 32 connected to the antenna connection terminal 100. Accordingly, the amount of heat generated near the terminal 31 is large, and the temperature near the terminal 31 is likely to increase. Accordingly, by shortening the heat transfer path from the vicinity of the terminal 31 in which a temperature is more likely to increase to the temperature sensor 40 via the metal shield 93, the measurement accuracy and/or time response of the temperature of the high-temperature part of the transmission filter 30 can be improved. As a result, deterioration and/or a failure due to the heat of the transmission filter 30 can be suppressed.

For example, in the radio frequency module 1B according to the present embodiment, the integrated circuit 82B may be stacked on the power amplifier 10.

This can contribute to the miniaturization of the radio frequency module 1B.

The communication device 5 according to the present embodiment includes the RFIC 3 configured to process a radio frequency signal and the radio frequency module 1B configured to transmit the radio frequency signal between the RFIC 3 and the antenna 2.

With this configuration, the effect of the above radio frequency module 1B can be obtained in the communication device 5.

### Fourth Embodiment

Next, the fourth embodiment will be described. The present embodiment mainly differs from the above third embodiment in that the integrated circuit including the PA control circuit and the temperature sensor is disposed between the power amplifier 10 and the transmission filter 30. The present embodiment will be described below with reference to the drawings, focusing on points different from the third embodiment.

The circuit configuration of a radio frequency module according to the present embodiment is the same as that of the radio frequency module according to the first embodiment, and the illustration and description thereof will therefore be omitted.

### 4.1 Installation Example of Radio Frequency Module 1C

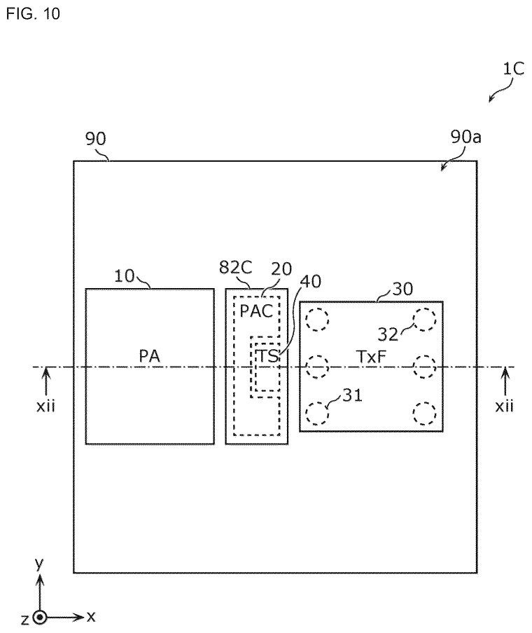

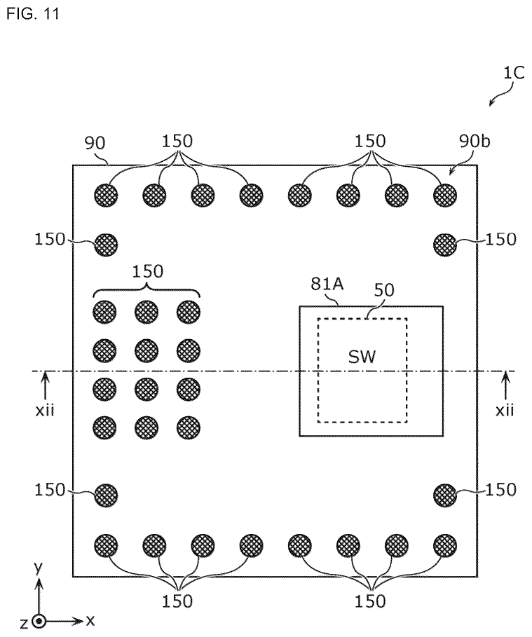

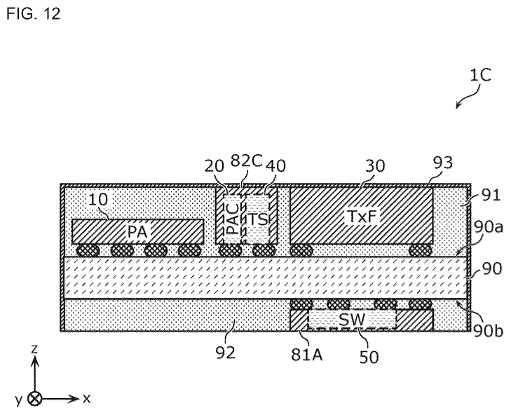

The installation example of a radio frequency module 1C will be described with reference to FIGS. 10 to 12. FIG. 10 is a plan view of the radio frequency module 1C according to the present embodiment, with the main surface 90a of the module substrate 90 viewed from the Z-axis positive side. FIG. 11 is a plan view of the radio frequency module 1C according to the present embodiment, with the main surface 90b of the module substrate 90 seen through from the Z-axis positive side. FIG. 12 is a cross-sectional view of the radio frequency module 1C according to the present embodiment. The cross section of the radio frequency module 1C in FIG. 12 is taken along line xii-xii in FIGS. 10 and 11.

In FIGS. 10 to 12, some of components are provided with letters representing the components so that the arrangement relationship of the components can be easily understood, but actual components do not necessarily have to be provided with such letters. In FIGS. 10 and 11, the illustration of the resin members 91 and 92 covering components on the main surfaces 90a and 90b of the module substrate 90 and the metal shield 93 covering the surfaces of the resin members 91 and 92 is omitted.

FIGS. 10 to 12 illustrate an exemplary configuration of the radio frequency module 1C, and the radio frequency module 1C can be installed using any of various circuit installations and circuit techniques. Accordingly, the following description of the radio frequency module 1C should not be interpreted in a limited manner.

The radio frequency module 1C includes the integrated circuit 81A, an integrated circuit 82C, the module substrate 90, the resin members 91 and 92, the metal shield 93, and the multiple external connection terminals 150 in addition to the multiple circuit components illustrated in FIG. 1.

Like in the first embodiment to the third embodiment, the transmission filter 30 (TxF) is disposed on the main surface 90a of the module substrate 90 and is in contact with the metal shield 93. As illustrated in FIGS. 10 to 12, the transmission filter 30 is closer to the temperature sensor 40 in the integrated circuit 82C than the power amplifier 10. The transmission filter 30 includes a plurality of external connection terminals including the terminals 31 and 32. The terminal 31 is an example of the first terminal, and the terminal 32 is an example of the second terminal. As illustrated in FIG. 10, the terminal 31 is closer to the integrated circuit 82C than the terminal 32.

The integrated circuit 82C is a semiconductor integrated circuit including the PA control circuit 20 (PAC) and the temperature sensor 40 (TS) and is disposed on the main surface 90a of the module substrate 90. Specifically, the integrated circuit 82C is disposed between the power amplifier 10 and the transmission filter 30. The integrated circuit 82C is in contact with the metal shield 93. That is, the integrated circuit 82C is directly and physically connected to the metal shield 93. Specifically, the top surface of the integrated circuit 82C is at least partly in contact with a part of the metal shield 93 formed on the top surface of the radio frequency module 1C. In the integrated circuit 82C, the temperature sensor 40 is closer to the transmission filter 30 than the PA control circuit 20.

The integrated circuit 82C does not necessarily have to include the PA control circuit 20 and may be, for example, an integrated circuit dedicated for the temperature sensor 40. In this case, the PA control circuit 20 may be included in another integrated circuit (e.g., the integrated circuit 81A or a new integrated circuit) different from the integrated circuit 82C.

### 4.2. Summarization

As described above, the radio frequency module 1C according to the present embodiment includes the module substrate 90, the transmission filter 30 disposed on the module substrate 90, the integrated circuit 82C that is disposed on the module substrate 90 and includes the temperature sensor 40, the resin members 91 and 92 that at least partly cover the transmission filter 30 and the integrated circuit 82C, and the metal shield 93 that at least partly covers surfaces of the resin members 91 and 92. The transmission filter 30 and the integrated circuit 82C are in contact with the metal shield 93.

With this configuration in which both the transmission filter 30 and the integrated circuit 82C are in contact with the metal shield 93, the integrated circuit 82C is thermally connected to the transmission filter 30 via the metal shield 93. Since the thermal conductivity of the metal shield 93 is higher than that of the resin members 91 and 92, the measurement accuracy and/or time response of the temperature of the transmission filter 30 can be improved. Assuming the power amplifier 10 is controlled on the basis of the temperature of the transmission filter 30 measured as described above, deterioration and/or a failure due to the heat of the transmission filter 30 can be suppressed.

For example, the radio frequency module 1C according to the present embodiment may further include the power amplifier 10 that is disposed on the module substrate 90 and is connected to the transmission filter 30. The power amplifier 10 does not necessarily have to be in contact with the metal shield 93.

With this configuration in which the power amplifier 10 is not in contact with the metal shield 93, the transfer of heat from the power amplifier 10 to the temperature sensor 40 via the metal shield 93 can be suppressed and the accuracy of measuring the temperature of the transmission filter 30 can be further improved.

For example, in the radio frequency module 1C according to the present embodiment, the module substrate 90 may have the main surfaces 90a and 90b facing each other. The transmission filter 30, the integrated circuit 82C, and the power amplifier 10 may be disposed on the main surface 90a.

With this configuration in which the transmission filter 30, the integrated circuit 82C, and the power amplifier 10 are disposed on the single main surface 90a of the module substrate 90, a production process can be simplified.

For example, the radio frequency module 1C according to the present embodiment may further include the PA control circuit 20 that is configured to control the power amplifier 10 and is included in the integrated circuit 82C.

With this configuration in which the temperature sensor 40 and the PA control circuit 20 are included in the single integrated circuit 82C, the number of components can be reduced as compared with the case where the temperature sensor 40 and the PA control circuit 20 are installed in the two respective components.

For example, in the radio frequency module 1C according to the present embodiment, the temperature sensor 40 may be closer to the transmission filter 30 than the PA control circuit 20 in the integrated circuit 82C.

With this configuration, the temperature sensor 40 can be disposed more closer to the metal shield 93. Accordingly, the heat transfer path from the transmission filter 30 to the temperature sensor 40 via the metal shield 93 can be shortened and the measurement accuracy and/or time response of the temperature of the transmission filter 30 can be further improved.

For example, in the radio frequency module 1C according to the present embodiment, the transmission filter 30 may include the terminal 31 connected to the power amplifier 10 and the terminal 32 connected to the antenna connection terminal 100. The terminal 31 may be closer to the integrated circuit 82C than the terminal 32.

With this configuration, the terminal 31 can be disposed more closer to the integrated circuit 82C. A larger amount of current flows through the terminal 31 connected to the power amplifier 10 than the terminal 32 connected to the antenna connection terminal 100. Accordingly, the amount of heat generated near the terminal 31 is large, and the temperature near the terminal 31 is likely to increase. Accordingly, by shortening the heat transfer path from the vicinity of the terminal 31 in which a temperature is more likely to increase to the temperature sensor 40 via the metal shield 93, the measurement accuracy and/or time response of the temperature of the high-temperature part of the transmission filter 30 can be improved. As a result, deterioration and/or a failure due to the heat of the transmission filter 30 can be suppressed.

For example, in the radio frequency module 1C according to the present embodiment, the integrated circuit 82C may be disposed between the power amplifier 10 and the transmission filter 30. The transmission filter 30 may be closer to the temperature sensor 40 than the power amplifier 10.

With this configuration, the transmission filter 30 can be disposed more closer to the temperature sensor 40. Accordingly, the heat transfer path from the transmission filter 30 to the temperature sensor 40 via the metal shield 93 can be shortened and the measurement accuracy and/or time response of the temperature of the transmission filter 30 can be further improved.

The communication device 5 according to the present embodiment includes the RFIC 3 configured to process a radio frequency signal and the radio frequency module 1C configured to transmit the radio frequency signal between the RFIC 3 and the antenna 2.

With this configuration, the effect of the above radio frequency module 1C can be obtained in the communication device 5.

### Other Embodiments

A radio frequency module according to the present disclosure and a communication device according to the present disclosure have been described on the basis of the embodiments, but are not limited to the above embodiments. The present disclosure also includes other embodiments realized by combining optional constituent elements in the above embodiments, modifications obtained by making various changes, which are conceived by those skilled in the art, to the above embodiments without departing from the spirit and scope of the present disclosure, and various devices including the above radio frequency module or the above communication device.

For example, in the circuit configuration of a radio frequency module or a communication device according to each of the above embodiments, another circuit element and another wiring line may be inserted between each of the circuit elements and the path connecting the signal paths, which are illustrated in the drawings. For example, in the radio frequency modules 1, 1A, 1B, and 1C, an impedance matching circuit may be connected between the power amplifier 10 and the transmission filter 30 and/or between the transmission filter 30 and the antenna connection terminal 100.

For example, the first embodiment and the second embodiment may be combined. In this case, a radio frequency module may include an integrated circuit including the PA control circuit 20, the switch circuit 50, and the temperature sensor 40.

The features of the radio frequency module and the communication device described on the basis of the above embodiments will be described below.

<1>

A radio frequency module comprising:
a module substrate;
a transmission filter disposed on the module substrate;
an integrated circuit that is disposed on the module substrate and includes a temperature sensor;
a resin member that at least partly covers the transmission filter and the integrated circuit; and
a metal shield that at least partly covers a surface of the resin member,
wherein the transmission filter and the integrated circuit are in contact with the metal shield.
   <2>

The radio frequency module according to <1>, further comprising a power amplifier that is disposed on the module substrate and is connected to the transmission filter,
wherein the power amplifier is not in contact with the metal shield.
   <3>

The radio frequency module according to <2>,
wherein the module substrate has a first main surface and a second main surface facing each other,
wherein the transmission filter and the power amplifier are disposed on the first main surface, and
wherein the integrated circuit is disposed on the second main surface.
   <4>

The radio frequency module according to <3>, further comprising a switch circuit that is connected between the transmission filter and an antenna connection terminal and is included in the integrated circuit.

<5>

The radio frequency module according to <4>, wherein the temperature sensor is closer to the metal shield than the switch circuit in the integrated circuit.

<6>

The radio frequency module according to any one of <3> to <5>, further comprising a power amplifier (PA) control circuit that is configured to control the power amplifier and is included in the integrated circuit.

<7>

The radio frequency module according to <6>, wherein the temperature sensor is closer to the metal shield than the PA control circuit in the integrated circuit.

<8>

The radio frequency module according to <2>,
wherein the module substrate has a first main surface and a second main surface facing each other, and
wherein the transmission filter, the integrated circuit, and the power amplifier are disposed on the first main surface.
   <9>

The radio frequency module according to <8>, further comprising a PA control circuit that is configured to control the power amplifier and is included in the integrated circuit.

<10>

The radio frequency module according to <9>, wherein the temperature sensor is closer to the transmission filter than the PA control circuit in the integrated circuit.

<11>

The radio frequency module according to any one of <8> to <10>,
wherein the transmission filter includes a first terminal connected to the power amplifier and a second terminal connected to an antenna connection terminal, and
wherein the first terminal is closer to the integrated circuit than the second terminal.
   <12>

The radio frequency module according to any one of <9> to <11>, wherein the integrated circuit is stacked on the power amplifier.

<13>

The radio frequency module according to any one of <8> to <11>,
wherein the integrated circuit is disposed between the power amplifier and the transmission filter, and
wherein the transmission filter is closer to the temperature sensor than the power amplifier.
   <14>

A communication device comprising:
a signal processing circuit configured to process a radio frequency signal; and
the radio frequency module according to any one of <1> to <13>, the radio frequency module being configured to transmit the radio frequency signal between the signal processing circuit and an antenna.

The present disclosure is widely applicable for use in a communication device, such as a cellular phone, as a radio frequency module disposed in a front-end portion.

What is claimed is:

1. A radio frequency module comprising:
a module substrate;
a transmission filter disposed on the module substrate;
an integrated circuit that is disposed on the module substrate and includes a temperature sensor;
a resin member that at least partly covers the transmission filter and the integrated circuit; and
a metal shield that at least partly covers a surface of the resin member,
wherein the transmission filter and the integrated circuit are in contact with the metal shield.

2. The radio frequency module according to claim 1, further comprising a power amplifier that is disposed on the module substrate and is connected to the transmission filter,
wherein the power amplifier is not in contact with the metal shield.

3. The radio frequency module according to claim 2,
wherein the module substrate has a first main surface and a second main surface facing each other,
wherein the transmission filter and the power amplifier are disposed on the first main surface, and
wherein the integrated circuit is disposed on the second main surface.

4. The radio frequency module according to claim 3, further comprising a switch circuit that is connected between the transmission filter and an antenna connection terminal and is included in the integrated circuit.

5. The radio frequency module according to claim 4, wherein the temperature sensor is closer to the metal shield than the switch circuit in the integrated circuit.

6. The radio frequency module according to claim 5, further comprising a power amplifier (PA) control circuit that is configured to control the power amplifier and is included in the integrated circuit.

7. The radio frequency module according to claim 6, wherein the temperature sensor is closer to the metal shield than the PA control circuit in the integrated circuit.

8. The radio frequency module according to claim 2,
wherein the module substrate has a first main surface and a second main surface facing each other, and
wherein the transmission filter, the integrated circuit, and the power amplifier are disposed on the first main surface.

9. The radio frequency module according to claim 8, further comprising a PA control circuit that is configured to control the power amplifier and is included in the integrated circuit.

10. The radio frequency module according to claim 9, wherein the temperature sensor is closer to the transmission filter than the PA control circuit in the integrated circuit.

11. The radio frequency module according to claim 10,
wherein the transmission filter includes a first terminal connected to the power amplifier and a second terminal connected to an antenna connection terminal, and
wherein the first terminal is closer to the integrated circuit than the second terminal.

12. The radio frequency module according to claim 10, wherein the integrated circuit is stacked on the power amplifier.

13. The radio frequency module according to claim 10,
wherein the integrated circuit is disposed between the power amplifier and the transmission filter, and
wherein the transmission filter is closer to the temperature sensor than the power amplifier.

14. A communication device comprising:
a signal processing circuit configured to process a radio frequency signal; and
the radio frequency module according to claim 1, the radio frequency module being configured to transmit the radio frequency signal between the signal processing circuit and an antenna.

15. The radio frequency module according to claim 3, further comprising a power amplifier (PA) control circuit that is configured to control the power amplifier and is included in the integrated circuit.

16. The radio frequency module according to claim 15, wherein the temperature sensor is closer to the metal shield than the PA control circuit in the integrated circuit.

17. The radio frequency module according to claim 4, further comprising a power amplifier (PA) control circuit that is configured to control the power amplifier and is included in the integrated circuit.

18. The radio frequency module according to claim 17, wherein the temperature sensor is closer to the metal shield than the PA control circuit in the integrated circuit.

19. The radio frequency module according to claim 8,
wherein the transmission filter includes a first terminal connected to the power amplifier and a second terminal connected to an antenna connection terminal, and
wherein the first terminal is closer to the integrated circuit than the second terminal.

20. The radio frequency module according to claim 9,
wherein the transmission filter includes a first terminal connected to the power amplifier and a second terminal connected to an antenna connection terminal, and
wherein the first terminal is closer to the integrated circuit than the second terminal.
